(19) United States
(12) Patent Application Publication
(10) Pub. No.: US 2025/0147571 A1
(43) Pub. Date: May 8, 2025

(54) ELECTRONIC DEVICE AND ENERGY HARVESTING METHOD THEREOF

(71) Applicant: SAMSUNG ELECTRONICS CO., LTD., Suwon-si (KR)

(72) Inventors: Guehwan MA, Suwon-si (KR); Gwirang PARK, Suwon-si (KR)

(73) Assignee: SAMSUNG ELECTRONICS CO., LTD., Suwon-si (KR)

(21) Appl. No.: 18/828,732

(22) Filed: Sep. 9, 2024

Related U.S. Application Data
(63) Continuation of application No. PCT/KR2024/013017, filed on Aug. 30, 2024.

(30) Foreign Application Priority Data
Nov. 2, 2023 (KR) 10-2023-0149589

(51) Int. Cl. G06F 1/3234; G06F 1/3218; H02J 50/00; H02J 50/20; H02J 50/30; H02N 2/18; H10N 19/00

(52) U.S. Cl. CPC G06F 1/3234; G06F 1/3218; H02J 50/001; H02J 50/20; H02J 50/30; H02J 2310/62; H02N 2/186; H10N 19/00

(57) ABSTRACT

An electronic device including: at least one power management integrated circuit (PMIC) configured to convert energy generated by at least one component of the electronic device into electrical energy; a memory storing at least one instruction; and at least one processor electrically connected to the memory and configured to execute the at least one instruction, where the at least one processor is configured to: determine an operation state of the at least one component; determine whether to drive at least one corresponding PMIC, based on the operation state; and drive the at least one corresponding PMIC based on the determination of whether to drive the at least one PMIC.

### CROSS-REFERENCE TO RELATED APPLICATIONS

This application is a continuation application of International Application No. PCT/KR2024/013017 designating the United States, filed on Aug. 30, 2024, in the Korean Intellectual Property Receiving Office, which claims priority from Korean Patent Application No. 10-2023-0149589, filed on Nov. 2, 2023, in the Korean Intellectual Property Office, the disclosures of which are hereby incorporated by reference herein in their entireties.

### BACKGROUND

### 1. Field

This disclosure relates to an electronic device and an energy harvesting method thereof that may determine whether to drive at least one corresponding harvesting unit based on the operating state of at least one component of the electronic device.

### 2. Description of Related Art

Energy harvesting refers to a technology that re-harvests energy leaking from various energy sources such as heat, light, vibration, and electromagnetic waves, converts them into electrical energy, and uses them.

A method of using electrical energy re-harvested by energy harvesting as a driving power source in electronic devices may be considered. In this case, it may be necessary to minimize the standby power consumption of the energy harvesting circuit.

### SUMMARY

Provided is an electronic device and a method for energy harvesting.

Further provided is an electronic device for determining whether to drive at least one corresponding harvesting unit, based on the operation state of at least one component of an electronic device, and an energy harvesting method thereof.

Further provided is an electronic device and method for converting and storing collected leakage energy into electrical energy and providing power to at least one low power operation module in a standby mode in which power is cut off.

Additional aspects will be set forth in part in the description which follows and, in part, will be apparent from the description, or may be learned by practice of the presented embodiments.

According to an aspect of the disclosure, an electronic device may include: at least one power management integrated circuit (PMIC) configured to convert energy generated by at least one component of the electronic device into electrical energy; a memory storing at least one instruction; and at least one processor electrically connected to the memory and configured to execute the at least one instruction, where the at least one processor is configured to: determine an operation state of the at least one component; determine whether to drive at least one corresponding PMIC, based on the operation state; and drive the at least one corresponding PMIC based on the determination of whether to drive the at least one PMIC.

The at least one PMIC may include: at least one of a photoelectric element PMIC, a radio frequency (RF) PMIC, a thermoelectric PMIC, and a piezoelectric PMIC.

The at least one component of the electronic device may include at least one of a display panel, a speaker, a wireless communication interface, a direct current (DC) power supply, a dimming controller, the at least one processor, and a main board on which the at least one processor is mounted.

The operation state of the at least one component may include at least one of a state in which a backlight of the display panel is in an on state, a state in which a volume of the speaker is equal to or larger than a predetermined volume, a state in which the wireless communication interface is operating, and a state in which a temperature of any of the DC power supply, the dimming controller, the at least one processor, and the main board is equal to or larger than a predetermined temperature.

The energy may include at least one of light energy, vibration energy, RF energy, and thermal energy.

The light energy may be generated while a backlight of the display panel is in an on state, the vibration energy may be generated when a volume of the speaker is equal to or larger than a predetermined volume, the RF energy may be generated while the wireless communication interface is operating, and the thermal energy may be generated when a temperature of any of the DC power supply, the dimming controller, the at least one processor, and the main board is larger than or equal to a predetermined temperature.

The electronic device may be further include: a charging supply configured to store electrical energy converted by the at least one PMIC.

The electronic device may further include: a standby mode power supply configured to convert the electrical energy stored in the charging supply into power and provide the converted power to at least one low power operation module in a standby mode in which power is cut off.

The low power operation module may include a microcomputer, a Wi-Fi module, a Bluetooth module, and an infrared (IR) module.

According to an aspect of the disclosure, a method for energy harvesting by an electronic device may include: determining an operation state of at least one component of the electronic device; determining whether to drive at least one corresponding PMIC, based on the operation state; driving the at least one corresponding PMIC based on determining whether to drive the at least one PMIC; and converting energy generated by the at least one component into electrical energy in response to driving the at least one corresponding PMIC.

The at least one PMIC may include at least one of a photoelectric element PMIC, a radio frequency (RF) PMIC, a thermoelectric PMIC, and a piezoelectric PMIC.

The at least one component of the electronic device may include at least one of a display panel, a speaker, a wireless communication interface, a direct current (DC) power supply, a dimming controller, at least one processor, and a main board on which the at least one processor is mounted.

The operation state of the at least one component may include at least one of a state in which a backlight of the display panel is in an on state, a state in which a volume of the speaker is equal to or larger than a predetermined volume, a state in which the wireless communication interface is operating, and a state in which a temperature of any one of the DC power supply, the dimming controller, the at least one processor, and the main board is equal to or larger than a predetermined temperature.

The energy may include at least one of light energy, vibration energy, RF energy, and thermal energy.

The light energy may be generated while a backlight of the display panel is in an on state, the vibration energy may be generated when a volume of the speaker is equal to or larger than a predetermined volume, the RF energy may be generated while the wireless communication interface is operating, and the thermal energy may be generated when a temperature of any of the DC power supply, the dimming controller, the at least one processor, and the main board is larger than or equal to a predetermined temperature.

The method may further include storing electrical energy converted by the driven at least one PMIC.

The method may further include converting the stored electrical energy into power and providing the converted power to at least one low power operation module in a standby mode in which power is cut off.

The low power operation module may include a microcomputer, a Wi-Fi module, a Bluetooth module, and an IR module.

Effects achievable in example embodiments of the disclosure are not limited to the above-mentioned effects, but other effects not mentioned may be apparently derived and understood by one of ordinary skill in the art to which example embodiments of the disclosure pertain, from the following description. In other words, unintended effects in practicing embodiments of the disclosure may also be derived by one of ordinary skill in the art from example embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic view illustrating an energy harvesting electronic device according to an embodiment of the disclosure;

FIG. 2 is a view illustrating components of an electronic device generating thermal energy according to an embodiment of the disclosure;

FIG. 3 is a view illustrating a component of an electronic device generating vibration energy according to an embodiment of the disclosure;

FIG. 4 is a view illustrating a component of an electronic device generating light energy according to an embodiment of the disclosure;

FIG. 5 illustrates a component of an electronic device generating RF energy according to an embodiment of the disclosure;

FIG. 6 is a schematic block view illustrating an electronic device according to an embodiment of the disclosure;

FIG. 7 is a circuit diagram illustrating an electronic device according to an embodiment of the disclosure;

FIG. 8 is a schematic flowchart illustrating an energy harvesting method by an electronic device according to an embodiment of the disclosure; and

FIG. 9A, FIG. 9B, FIG. 9C, and FIG. 9D are flowcharts illustrating determining whether to drive a harvesting unit according to an embodiment of the disclosure.

### DETAILED DESCRIPTION

Hereinafter, example embodiments of the disclosure will be described in detail with reference to the accompanying drawings. The embodiments described herein are example embodiments, and thus, the disclosure is not limited thereto and may be realized in various other forms. The same or similar reference denotations may be used to refer to the same or similar elements throughout the specification and the drawings. Further, the terms including technical or scientific terms used in the disclosure may have the same meanings as generally understood by those skilled in the art.

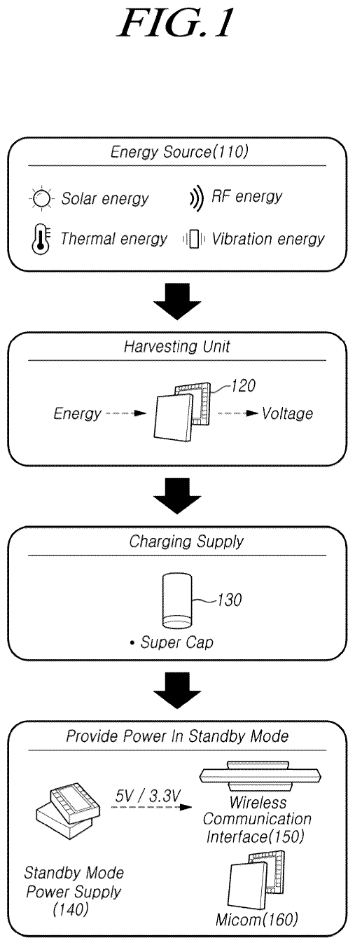

FIG. 1 is a schematic view illustrating an energy harvesting electronic device according to an embodiment of the disclosure.

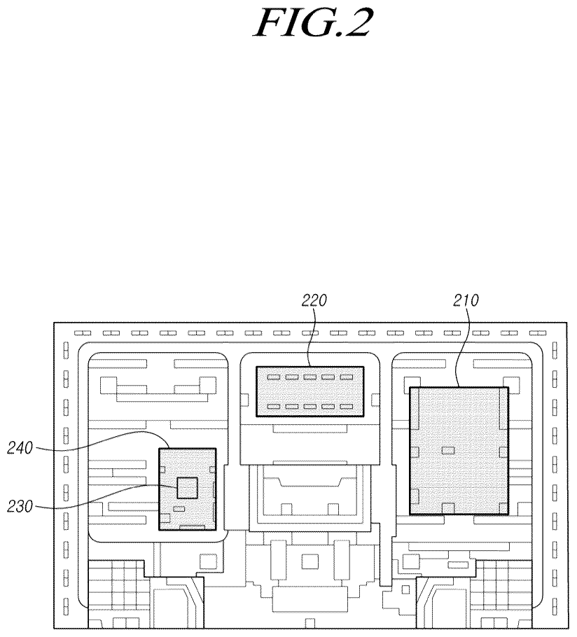

According to an embodiment, leakage energy due to various energy sources 110 may be generated in the electronic device. The leakage energy may include at least one of thermal energy, vibration energy, light (or solar) energy, and radio frequency (RF) energy. Components (or modules) of the electronic device that generate the at least one leakage energy are described below with reference to FIGS. 2 to 5.

According to an embodiment, the electronic device may include at least one harvesting unit 120 for converting the at least one leakage energy into electrical energy. Each harvesting unit 120 may include any one of a photoelectric element harvesting unit, an RF harvesting unit, a thermoelectric element harvesting unit, and a piezoelectric element harvesting unit. Alternatively, each harvesting unit 120 may include at least one of a photoelectric element harvesting unit, an RF harvesting unit, a thermoelectric element harvesting unit, and a piezoelectric element harvesting unit. The harvesting unit 120 may be implemented as a power management integrated circuit (PMIC) that generates electrical energy using each energy harvesting element and manages the generated electrical energy, but is not limited thereto. Thus, throughout the specification, reference to the “harvesting unit” should be understood as referring to one or more PMICs. The harvesting unit 120 may include a reconfigurable converter and a control circuit.

According to an embodiment, the electronic device may determine an operation state of at least one component of the electronic device, and may determine whether to drive at least one corresponding harvesting unit, based on the operation state. The electronic device may drive the at least one corresponding harvesting unit, based on determining whether to drive the electronic device. The electronic device may convert at least one leakage energy generated by at least one corresponding component into electrical energy by the driven at least one harvesting unit.

According to an embodiment, the at least one component may include at least one of a display panel, a speaker, a wireless communication interface, a direct current (DC) power supply, a dimming controller, a processor, and a main board on which the processor is mounted.

According to an embodiment, the operation state of the at least one component may include at least one of a state in which the backlight of the display panel is turned on, a state in which the volume of the speaker is equal to or larger than a predetermined volume, a state in which the wireless communicator is operating, and a state in which the temperature of any one of the DC power supply, the dimming controller, the processor, and the main board is equal to or larger than a predetermined temperature.

According to an embodiment, the light energy may be generated while the backlight of the display panel is turned on. The vibration energy may be generated when the volume of the speaker is larger than or equal to the predetermined volume. The RF energy may be generated while the wireless communication interface is operating. The thermal energy may be generated when the temperature of any one of the DC power supply, the dimming controller, the processor, and the main board is equal to or higher than the predetermined temperature.

According to an embodiment, the electronic device may further include a charging supply 130. The charging supply 130 may store the electrical energy converted by at least one harvesting unit. The charging supply 130 may include at least one of a battery and a super capacitor 130, but is not limited thereto. The battery may store chemical energy of ions (e.g., lithium ions) released by causing a chemical reaction (e.g., oxidation reaction) to electricity. The supercapacitor 130 may store physical energy (e.g., the amount of charge) in the ion layer formed on the surface of the electric double layer using the electrostatic phenomenon of charge.

According to an embodiment, the electronic device may further include a standby mode power supply 140. The standby mode power supply 140 may provide power to at least one low power operation module in the standby mode in which power is cut off by converting electrical energy stored in the charging supply 130 into a predetermined voltage. The low power operation module may include a microcomputer 160 (or micro-processor computer: MiCom) and a wireless communication interface 150. The wireless communication interface 150 may include, but is not limited to, at least one of a Wi-Fi module, a Bluetooth module, an IR module, a UWB module, and a Zigbee module. In the illustrated example, the standby mode power supply 140 may convert the amount of charge stored in the charging supply 130 into a predetermined voltage (e.g., 5 V or 3.3 V) capable of driving the low power operation module, and may provide power to at least one low power operation module in the standby mode in which power is cut off.

FIG. 2 is a view illustrating components of an electronic device generating thermal energy according to an embodiment of the disclosure.

Referring to the illustrated example, the thermal energy may be generated based on driving of any one of the DC power supply (e.g., switching mode power supply (SMPS)) 210, the dimming controller 220, the processor 230, and various semiconductors mounted on the main board 240, but is not limited thereto. The DC power supply 210 may receive alternating current (AC) power from a power source, convert the AC power into DC power, and then supply DC power to other electronic components. The DC power supply 210 may include a switching transistor, and may supply DC power to other electronic components based on the switching operation. The dimming controller 220 may control backlight luminance and compensate for image data by adjusting a dimming value (or duty) based on input image analysis. In the illustrated example, the positions of the DC power supply 210, the dimming controller 220, and the processor 230 are merely an example, and it will be understood by one of ordinary skill in the art that the electronic device is not limited to a specific position.

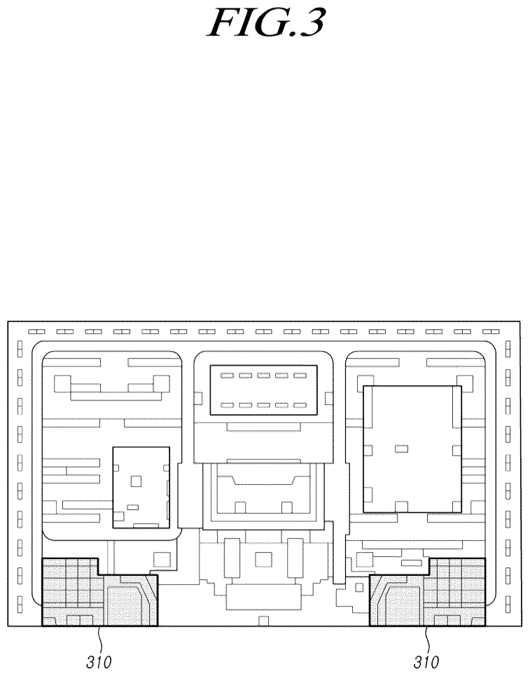

FIG. 3 is a view illustrating a component of an electronic device generating vibration energy according to an embodiment of the disclosure.

Referring to the illustrated example, the vibration energy may be generated based on driving of the speaker 310. The vibration energy may be generated based on the frequency of the vibration of the speaker 310. According to an embodiment, the speaker 310 may include a vibrator and may output sound. The speaker 310 may convert an electrical signal into vibration energy by stimulating the vibrator and output sound. In the illustrated example, the speaker 310 is positioned on one side portion (e.g., a lower end portion) of the electronic device, but is not limited thereto.

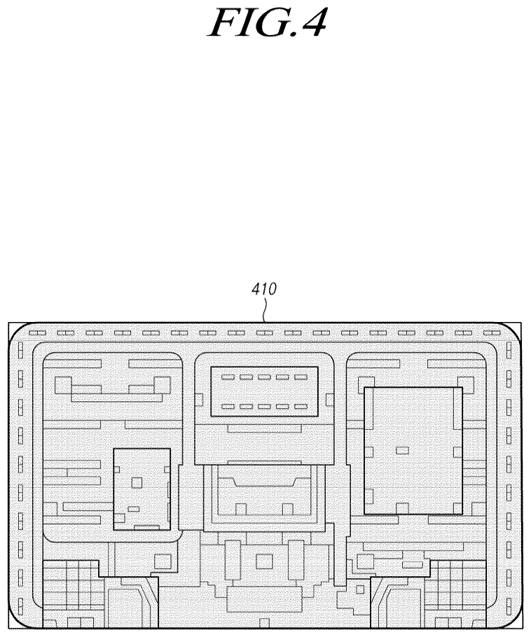

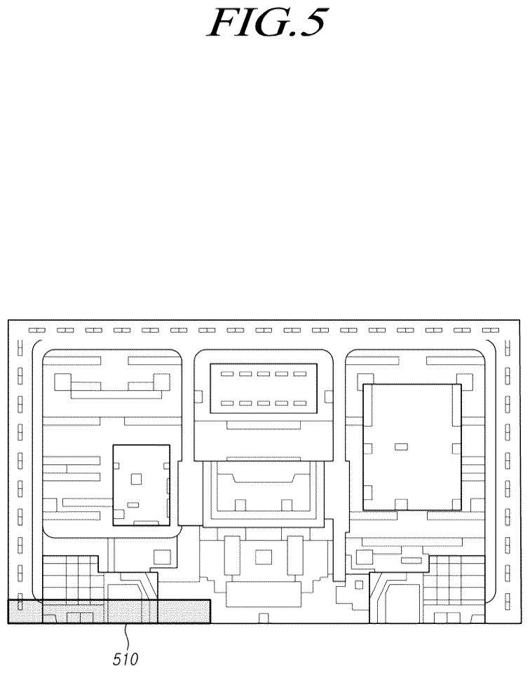

FIG. 4 is a view illustrating a component of an electronic device generating light energy according to an embodiment of the disclosure.

Referring to the illustrated example, the light energy may be generated based on driving of the backlight of the display panel 410 inside the electronic device. The light energy may include light energy naturally present outside the electronic device. In the illustrated example, the position of the display panel 410 is merely an example, and it will be understood by those skilled in the art that the position of the display panel 410 is not limited to a specific position in the electronic device.

FIG. 5 illustrates a component of an electronic device generating RF energy according to an embodiment of the disclosure.

Referring to the illustrated example, the RF energy may be generated in a wireless antenna based on driving of the wireless communication interface. The wireless communication interface may include, but is not limited to, at least one of a Wi-Fi module, a Bluetooth module, a UWB module, and a Zigbee module. The wireless antenna may include, but is not limited to, a Wi-Fi antenna 510, a Bluetooth antenna, a UWB antenna, and a Zigbee antenna. In the illustrated example, the Wi-Fi antenna 510 is positioned on one side (e.g., a lower end) of the electronic device, but is not limited thereto.

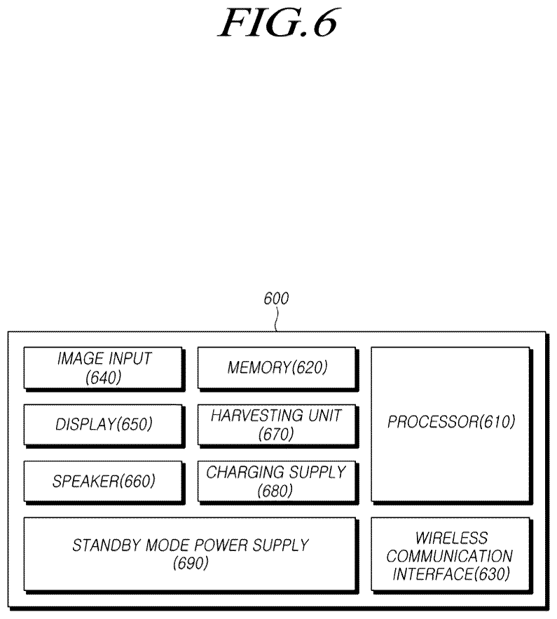

FIG. 6 is a block diagram schematically illustrating an electronic device according to an embodiment of the disclosure.

Referring to FIG. 6, an electronic device 600 may include a processor 610, memory 620, a wireless communication interface 630, an image input 640, a display 650, a speaker 660, a harvesting unit 670, a charging supply 680, and a standby mode power supply 690. There may be provided one or more harvesting units 670. The electronic device 600 may further include at least one of a microcomputer 160, a direct current (DC) power supply 210, a dimming controller 220, a main board 240 on which the processor 610 is mounted, or a wired communication interface. The harvesting unit 670, the charging supply 680, and the standby mode power supply 690 may correspond to the harvesting unit 120, the charging supply 130, and the standby mode power supply 140, respectively, illustrated in FIG. 1. The electronic device 600 may include additional components other than the illustrated components, or may omit at least one of the illustrated components.

According to an embodiment, the electronic device 600 may include a user device capable of performing various computing functions, such as video viewing and communication. The electronic device 600 may include, but are not limited to, TVs, desktop computers, smart phones, laptop computers, tablet PCs, mobile phones, personal digital assistants (PDAs), laptops, media players, e-book terminals, digital broadcasting terminals, navigation devices, kiosks, digital cameras, home appliances, and other mobile or non-mobile computing devices. The electronic device 600 may be wearable terminals, such as watches and glasses, capable of performing various computing functions, such as video watching and communication. The electronic device 600 may be various types of terminals without being limited to the above examples.

According to an embodiment, the memory 620 is a storage medium used by the electronic device 600 and may store data, such as at least one instruction or configuration information corresponding to at least one program. The program may include an operating system (OS) program and various application programs. The memory 620 may be configured as a volatile memory, a non-volatile memory, or a combination of a volatile memory and a non-volatile memory. The memory 620 may provide the stored data according to a request of the processor 610.

According to an embodiment, the image input 640 may receive images and image information through a tuner, an input/output unit, a wired communication interface, or the wireless communication interface 630. The image information may include image metadata including, e.g., identification information, genre information, cast information, and character information about the image. To that end, the image input 640 may include at least one of the tuner and the input/output unit. The tuner may tune and select only the frequency of the broadcast channel to be received by the electronic device 600 among many radio components, by amplifying, mixing, and resonating the broadcast signals wiredly/wirelessly received. The broadcast signal may include video, audio, and additional data (e.g., electronic program guide (EPG)). The tuner may receive real-time broadcast channels (or real-time viewing images) from various broadcast sources, such as terrestrial broadcasts, cable broadcasts, satellite broadcasts, Internet broadcasts, and the like. The tuner may be implemented integrally with the electronic device 600 or may be implemented as a separate tuner electrically connected to the electronic device 600. The input/output unit may include at least one of a high definition multimedia interface (HDMI) input port, a component input jack, a PC input port, and a USB input jack capable of receiving an image and image information from an external device of the electronic device 600 under the control of the processor 610. It will be understood that the input/output unit may be added, deleted, and/or changed according to the performance and structure of the electronic device 600.

According to an embodiment, the display 650 may perform functions for outputting information in the form of numbers, characters, images, and/or graphics. The display 650 may include at least one display panel for output. The at least one display panel may include at least one display panel among, e.g., a liquid crystal display (LCD), a light emitting diode (LED), a light emitting polymer display (LPD), an organic light emitting diode (OLED), an active matrix organic light emitting diode (AMOLED), or flexible LED (FLED). The display panel may include a plurality of signal lines, such as a plurality of gate lines GL, a plurality of data lines DL, and a plurality of sensing lines SL, and a plurality of pixels PX, e.g., a pixel array, connected to the plurality of signal lines and arranged in a matrix form. The plurality of pixels PX may display one color among red, green, and blue, and may have a pixel displaying red, a pixel displaying green, and a pixel displaying blue arranged sequentially and repeatedly. The user may perceive one mixed color of red, green, and blue light displayed from adjacent pixels PX. The display 650 may display a screen corresponding to data received from the processor 610. The display 650 may be referred to as an ‘output unit’, a ‘display unit’, or by other terms having an equivalent technical meaning.

According to an embodiment, the wireless communication interface 630 may include a wireless communication interface enabling communication with an external device. The wireless communication interface 630 may include at least one of a wireless LAN communication interface and a short-range communication interface. The wireless LAN communication interface may include, e.g., Wi-Fi, and may support the wireless LAN standard (IEEE802.11x) of the institute of electrical and electronics engineers (IEEE). The wireless LAN communication interface may be wirelessly connected to an access point (AP) under the control of the processor 610. The short-range communication interface may perform short-range communication wirelessly with an external device under the control of the processor 610. Short-range communication may include Bluetooth, Bluetooth low energy, infrared data association (IrDA), ultra-wideband (UWB), and near-field communication (NFC). The external device may include a server device and a mobile terminal (e.g., phone, tablet, etc.) providing, e.g., a video service.

According to an embodiment, the wired communication interface may include a wired communication interface enabling communication with an external device. The wired communication interface may include wired Ethernet.

According to an embodiment, the speaker 660 may include a vibrator and may output sound. The speaker 660 may stimulate the vibrator to switch the electrical signal into vibration energy and may output a sound.

According to an embodiment, the harvesting unit 670 may convert at least one leakage energy into electrical energy. There may be provided one or more harvesting units 670. Each harvesting unit 670 may include any one of a photoelectric element harvesting unit, an RF harvesting unit, a thermoelectric element harvesting unit, and a piezoelectric element harvesting unit. Alternatively, each harvesting unit 670 may include at least one of a photoelectric element harvesting unit, an RF harvesting unit, a thermoelectric element harvesting unit, and a piezoelectric element harvesting unit. The harvesting unit 670 may be implemented as a power management integrated circuit (PMIC) that generates electrical energy using each energy harvesting element and manages the generated electrical energy, but is not limited thereto. The harvesting unit 670 may include a reconfigurable converter and a control circuit.

According to an embodiment, the at least one leakage energy may include at least one of light energy, vibration energy, RF energy, and thermal energy. The light energy may be generated while the backlight of the display panel is turned on. The vibration energy may be generated when the volume of the speaker 660 is larger than or equal to the predetermined volume. The RF energy may be generated while the wireless communication unit 630 is operating. The thermal energy may be generated when the temperature of any one of the DC power supply unit 210, the dimming controller 220, the processor 610, and the main board on which the processor 610 is mounted is equal to or higher than the predetermined temperature.

According to an embodiment, the processor 610 may control at least one other component of the electronic device 600 and/or execute computation or data processing regarding communication by executing at least one instruction stored in the memory 620. The processor 610 may include at least one of a central processing unit (CPU), a graphic processing unit (GPU), a micro controller unit (MCU), a sensor hub, a supplementary processor, a communication processor, an application processor, an application specific integrated circuit (ASIC), or field programmable gate arrays (FPGA) and may have multiple cores.

According to an embodiment, the processor 610 may determine the operation state of at least one component of the electronic device 600. The at least one component may include at least one of the display panel, the speaker 660, the wireless communication interface 630, the DC power supply 210, the dimming controller 220, the processor 610, and the main board 240 on which the processor 610 is mounted. The operation state of the at least one component may include at least one of a state in which a backlight of the display panel is in an on state, a state in which a volume of the speaker 660 is equal to or larger than a predetermined volume, a state in which the wireless communication interface 630 is operating, and a state in which a temperature of any one of the DC power supply 210, the dimming controller 220, the processor 610, and the main board 240 is equal to or larger than a predetermined temperature.

According to an embodiment, the processor 610 may determine whether to drive the corresponding at least one harvesting unit based on the operation state.

According to an embodiment, the processor 610 may drive the corresponding at least one harvesting unit based on determining whether to drive. For example, when the backlight of the display panel of the electronic device 600 is turned on, the processor 610 may determine to drive the corresponding photoelectric element harvesting unit, and may set the power of the photoelectric element harvesting unit to ‘ON’ to drive the photoelectric element harvesting unit. For example, when the electronic device 600 is in a music listening mode or a background operation mode, the backlight of the display panel may be in the off state. When the backlight is in the off state, the processor 610 may control not to drive the photoelectric element harvesting unit by setting the power of the corresponding photoelectric element harvesting unit to ‘OFF’.

According to an embodiment, the charging supply 680 may store the electrical energy converted by the at least one harvesting unit 670. The charging supply 680 may include at least one of a battery and a super capacitor 130, but is not limited thereto. The battery may store chemical energy of ions (e.g., lithium ions) released by causing a chemical reaction (e.g., oxidation reaction) to electricity. The supercapacitor 130 may store physical energy (e.g., the amount of charge) in the ion layer formed on the surface of the electric double layer using the electrostatic phenomenon of charge.

According to an embodiment, the standby mode power supply 690 may convert electrical energy stored in the charging supply 680 into power and provide the converted power to at least one low power operation module in the standby mode in which power is cut off. The low power operation module may include a microcomputer 160 and a wireless communication interface 630. The wireless communication interface 630 may include, but is not limited to, at least one of a Wi-Fi module, a Bluetooth module, an IR module, a UWB module, and a Zigbee module. For example, the standby mode power supply 690 may convert the amount of charge stored in the charging supply 680 into a predetermined voltage (e.g., 5 V or 3.3 V) capable of driving the low power operation module, and may provide power to at least one low power operation module in the standby mode in which power is cut off.

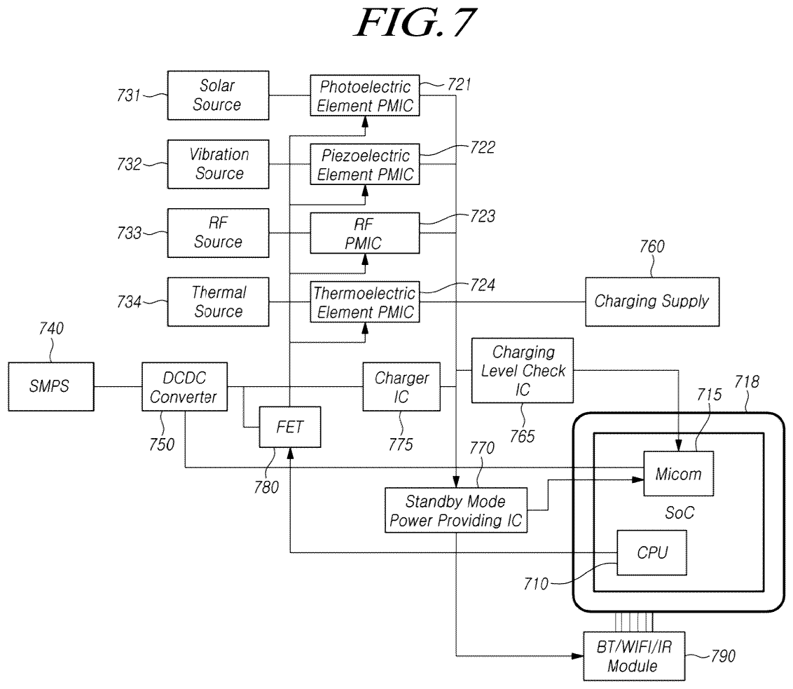

FIG. 7 is a circuit diagram illustrating an electronic device according to an embodiment of the disclosure.

In an embodiment, the switching mode power supply (SMPS) 740 may receive alternating current (AC) power from a power source, convert the AC power into DC power, and then supply DC power to other electronic components. The SMPS 740 may correspond to the DC power supply 210 of FIG. 2. The SMPS 740 may include a switching transistor, and may supply DC power to other electronic components based on the switching operation.

In an embodiment, the DCDC converter 750 may drop the input voltage to a lower output voltage or may boost the input voltage to a higher output voltage. For example, the DCDC converter 750 may drop an input voltage of 13V to 3.3V. The dropped voltage of 3.3V may be provided to the microcomputer 715.

In an embodiment, the photoelectric element PMIC 721 may convert light energy (e.g., light energy leaking while the backlight is in the on state) leaking from the light energy source 731 that generates light or sunlight into electrical energy. Due to the particle properties of light, the photoelectric element PMIC 721 may use the photoelectric effect in which electrons are emitted from the metal surface and current flows when light is applied to the metal. To that end, the photoelectric element PMIC 721 may include a photoelectric element. The photoelectric element PMIC 721 may include a solar cell composed of the photoelectric element. When photons are incident from the inside (e.g., the display panel 410) of the electronic device or from the outside of the electronic device, the photoelectric element PMIC 721 may generate electrical energy by emitting photons.

In an embodiment, the piezoelectric element PMIC 722 may convert vibration energy leaking from the vibration energy source 732 (e.g., vibration energy leaking from the speaker 310) into electrical energy. To that end, the piezoelectric element PMIC 722 may include a piezoelectric element. The piezoelectric element PMIC 722 may maximize and generate output power by adjusting its frequency to the ambient vibration frequency using the piezoelectric element. The frequency of the piezoelectric element matched to the frequency of the ambient vibration may be referred to as a resonance frequency. When the frequency of the ambient vibration matches the resonance frequency of the piezoelectric element, amplification of the displacement occurs, and thus the piezoelectric element PMIC 722 may generate the greatest electrical energy. The piezoelectric PMIC 722 may further include a rectifier. The piezoelectric element may output an alternating current (AC) voltage, and the rectifier may convert the AC voltage into a DC voltage.

In an embodiment, the RF PMIC 723 may convert RF energy from the RF energy source 733 into electrical energy. The RF PMIC 723 may be connected to a wireless antenna (e.g., the Wi-Fi antenna 510) and may include a rectifier. Since electromagnetic waves in the air consist of a magnetic field and an electric field that change, an alternating current may be generated in the wireless antenna according to the electromagnetic induction law. The RF PMIC 723 may amplify the alternating current generated in the wireless antenna and convert the amplified alternating current into a direct current.

In an embodiment, the thermoelectric element PMIC 724 may convert thermal energy leaking from the thermal energy source 734 (e.g., thermal energy leaking while the processor is in a state of being above a predetermined temperature) into electrical energy. The thermoelectric element PMIC 724 may generate electrical energy using the thermoelectric effect in which a temperature difference of an object is converted into a potential difference. The thermoelectric element may refer to an element that generates electrical energy using the thermoelectric effect. The thermoelectric element PMIC 724 may harvest electrical energy having a sufficiently high potential (e.g., about 1V or more) even when the temperature difference of the thermoelectric element is small (e.g., ΔT<10° C.). The thermoelectric element PMIC 724 may generate corresponding output power (e.g., 1 mW) even when the magnitude of the output voltage is small (e.g., 100 mV) due to a small temperature difference.

In an embodiment, the CPU 710 may determine the operation state of at least one component. The at least one component may include at least one of the display panel, the speaker 660, the wireless communication interface 630, the DC power supply 210, the dimming controller 220, the processor 610, and the main board 240 on which the processor 610 is mounted. The light energy source 731 may include the display panel. The vibration energy source 732 may include the speaker 660. The RF energy source 733 may include the wireless communication interface 630. The thermal energy source 734 may include the DC power supply 210, the dimming controller 220, the processor 610, and the main board 240 on which the processor 610 is mounted. The operation state of the at least one component may include at least one of a state in which a backlight of the display panel is in an on state, a state in which a volume of the speaker 660 is equal to or larger than a predetermined volume, a state in which the wireless communication interface 630 is operating, and a state in which a temperature of any one of the DC power supply 210, the dimming controller 220, the processor 610, and the main board 240 is equal to or larger than a predetermined temperature.

In an embodiment, the CPU 710 may determine whether to drive at least one corresponding PMIC, based on the operation state. According to an embodiment, the processor 610 may drive the at least one corresponding PMIC, based on determining whether to drive the PMIC.

In an embodiment, at least some of the components in the electronic device may be connected to each other through a communication method between peripheral electronic components (or modules) and may exchange signals (e.g., commands or data) with each other. The communication method between the electronic modules may include a bus, a general purpose input and output (GPIO), a serial peripheral interface (SPI), and a mobile industry processor interface (MIPI).

In an embodiment, the CPU 710 may include at least one general purpose input output (GPIO) port, which is a general purpose input/output port used to communicate with peripheral electronic modules. For example, the CPU 710 may include GPIO port #1 to GPIO port #4. GPIO ports #1 to #4 may be set to “ON” or “OFF” to control whether to drive the photoelectric element PMIC 721, the piezoelectric device PMIC 722, the RF PMIC 723, and the thermoelectric device PMIC 724 in order. For example, the CPU 710 may set GPIO port #1 to ‘ON’ when the backlight is in the on state, and may set GPIO port #3 to ‘ON’ when the BT/Wi-Fi/IR module 790 is in operation. When GPIO port #1 and GPIO port #3 are set to ‘ON’, the CPU 710 may control the FET 780 to drive the photoelectric element PMIC 721 and the RF PMIC 723. In an embodiment, the field effect transistor (FET) 780 may switch the channel through which a current flows under the control of the CPU 710. When GPIO port #1 and GPIO port #3 are set to “ON”, the FET 780 may drive the photoelectric element PMIC 721 and the RF PMIC 723 by switching the channel through which a current flows to the photoelectric element PMIC 721 and the RF PMIC 723.

In an embodiment, the charging supply 760 may include at least one of a battery and a super capacitor, but is not limited thereto. The battery may store chemical energy of ions (e.g., lithium ions) released by causing a chemical reaction (e.g., oxidation reaction) to electricity. The supercapacitor may store physical energy (e.g., the amount of charge) in the ion layer formed on the surface of the electric double layer using the electrostatic phenomenon of charge.

In an embodiment, a charging level check IC 765 may measure the level of electrical energy stored in the charging supply 760. When the measured level of electrical energy is larger than or equal to a predetermined level, the charger IC 775 may block the channel through which power is supplied from the SMPS 740, thereby receiving power from the charging supply 760.

In an embodiment, the standby mode power providing IC 770 may convert electrical energy stored in the charging supply 760 into power and provide the power to at least one low power operation module in the standby mode in which power is cut off. The low power operation module may include a microcomputer 715 and a BT/Wi-Fi/IR module 790. For example, the standby mode power providing IC 770 may convert the amount of charge stored in the charging supply 760 into a predetermined voltage (e.g., 5V) capable of driving the BT/Wi-Fi/IR module 790 and provide power to the BT/Wi-Fi/IR module 790 in the standby mode in which power is cut off.

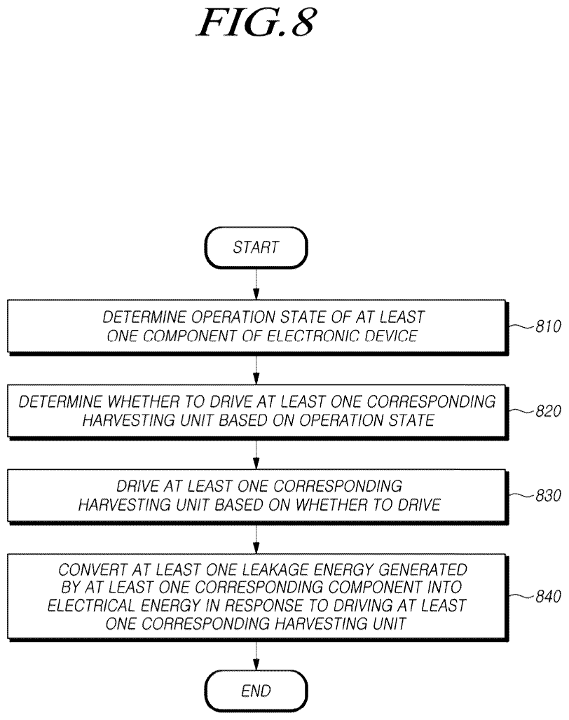

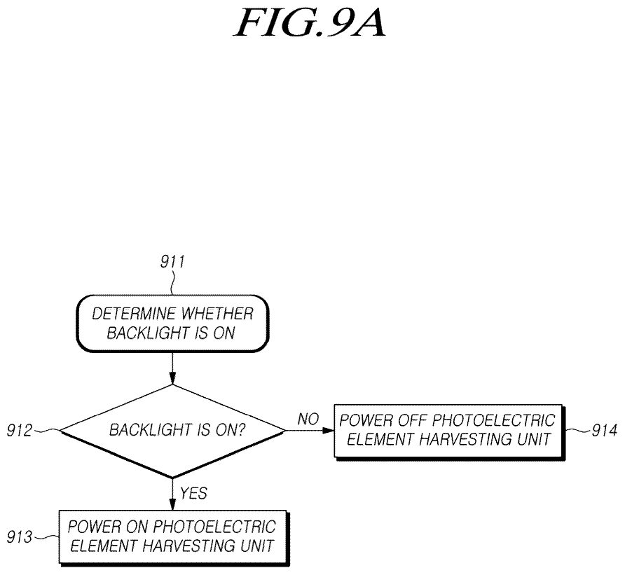

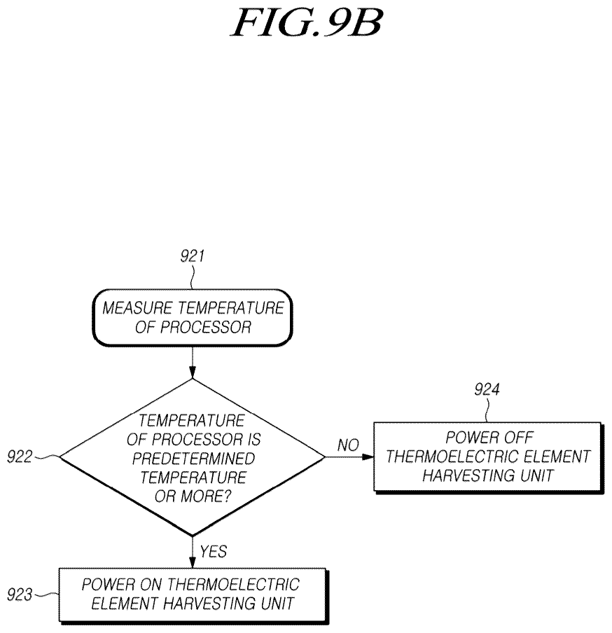

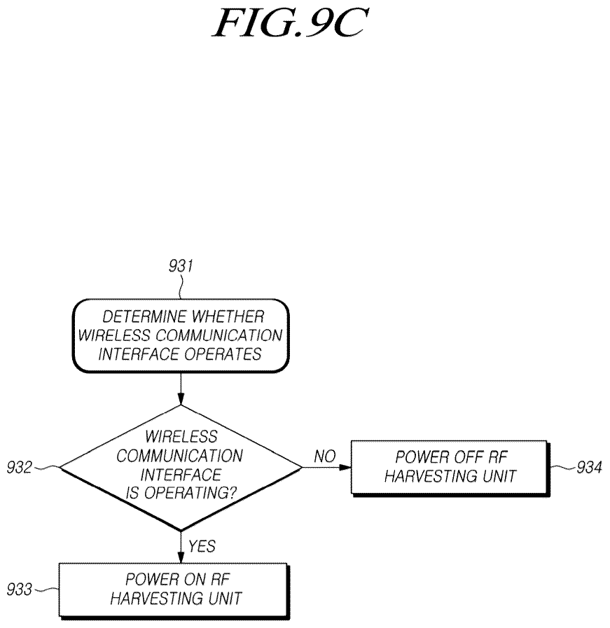

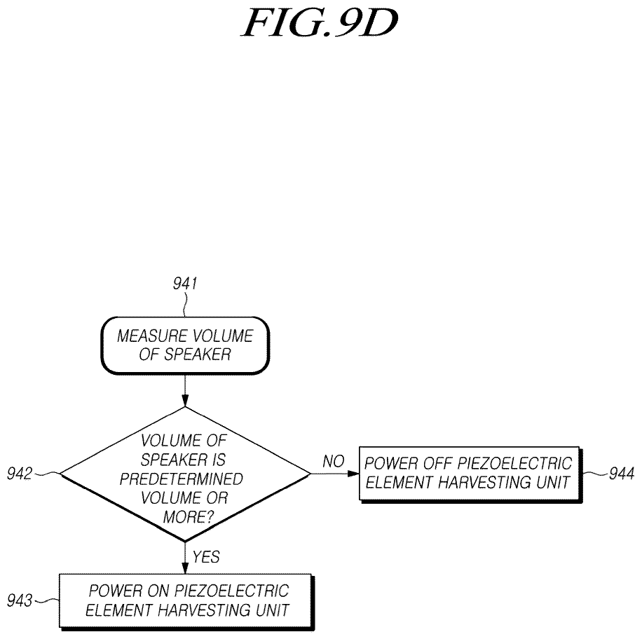

FIG. 8 is a schematic flowchart illustrating an energy harvesting method by an electronic device according to an embodiment of the disclosure. FIGS. 9A, 9B, 9C, and 9D are flowcharts illustrating determining whether to drive a harvesting unit according to an embodiment of the disclosure. The electronic device of FIGS. 8, 9A to 9D may be an electronic device corresponding to the electronic device 600 of FIG. 6. In the operation of the electronic device described in FIGS. 8, 9A to 9D, what overlaps those described in the previous paragraphs, such as for FIG. 6, may be omitted. Some of the operations illustrated in FIGS. 8, 9A to 9D may be omitted, and an operation not illustrated in FIGS. 8, 9A to 9D may be added.

Referring to FIG. 8, in operation 810, according to an embodiment, the electronic device 600 may determine the operation state of at least one component of the electronic device 600. The at least one component may include at least one of a display panel, a speaker, a wireless communication interface, a DC power supply, a dimming controller, a processor, and a main board on which the processor is mounted. the operation state of the at least one component may include at least one of a state in which a backlight of the display panel is in an on state, a state in which a volume of the speaker is equal to or larger than a predetermined volume, a state in which the wireless communication interface is operating, and a state in which a temperature of any one of the DC power supply, the dimming controller, the processor, and the main board is equal to or larger than a predetermined temperature.

In operation 820 according to an embodiment, the electronic device 600 may determine whether to drive the corresponding at least one harvesting unit based on the operation state.

In operation 830 according to an embodiment, the electronic device 600 may drive the corresponding at least one harvesting unit based on determining whether to drive.

Referring to FIG. 9A, in operation 911, according to an embodiment, the electronic device 600 may determine whether the backlight of the display panel is in the on state. For example, when the electronic device 600 is in a music listening mode or a background operation mode, the backlight of the display panel may be in the off state. When the backlight is in the on state, it may proceed to operation 913, and when the backlight is in the off state, it may proceed to operation 914. In operation 913, the electronic device 600 may control to drive the photoelectric element harvesting unit by setting the power of the photoelectric element harvesting unit to ‘ON’. In operation 914, the electronic device 600 may control not to drive the photoelectric element harvesting unit by setting the power of the photoelectric element harvesting unit to ‘OFF’.

Referring to FIG. 9B, in operation 921, the electronic device 600 may measure the temperature of the processor. When the temperature of the processor is higher than or equal to a predetermined temperature, it may proceed to operation 923, and when the temperature is lower than the predetermined temperature, it may proceed to operation 924. In operation 923, the electronic device 600 may control to drive the thermoelectric element harvesting unit by setting the power of the thermoelectric element harvesting unit to ‘ON’. In operation 924, the electronic device 600 may control not to drive the thermoelectric element harvesting unit by setting the power of the thermoelectric element harvesting unit to ‘OFF’.

Referring to FIG. 9C, in operation 931, according to an embodiment, the electronic device 600 may determine whether the wireless communication unit operates. When the wireless communication interface is in the operation state, it may proceed to operation 933, and when the wireless communication interface is not in the operation state, it may proceed to operation 934. In operation 933, the electronic device 600 may control to drive the RF harvesting unit by setting the power of the RF harvesting unit to ‘ON’. In operation 934, the electronic device 600 may control not to drive the RF harvesting unit by setting the power of the RF harvesting unit to ‘OFF’.

Referring to FIG. 9D, in operation 941, according to an embodiment, the electronic device 600 may measure the volume of the speaker. When the volume of the speaker is larger than or equal to a predetermined volume, it may proceed to operation 943, and when the volume is less than the predetermined volume, it may proceed to operation 944. In operation 943, the electronic device 600 may control to drive the piezoelectric element harvesting unit by setting the power of the piezoelectric element harvesting unit to ‘ON’. In operation 944, the electronic device 600 may control not to drive the piezoelectric element harvesting unit by setting the power of the piezoelectric element harvesting unit to ‘OFF’.

Referring back to FIG. 8, in operation 840, according to an embodiment, the electronic device 600 may convert at least one leakage energy into electrical energy by the at least one harvesting unit driven. The at least one leakage energy may include at least one of light energy, vibration energy, RF energy, and thermal energy. The light energy may be generated while the backlight of the display panel is turned on. The vibration energy may be generated when the volume of the speaker is larger than or equal to the predetermined volume. The RF energy may be generated while the wireless communication interface is operating. The thermal energy may be generated when the temperature of any one of the DC power supply, the dimming controller, the processor, and the main board is equal to or higher than the predetermined temperature.

According to an embodiment, the electronic device 600 may store the electrical energy converted by the at least one harvesting unit.

According to an embodiment, the electronic device 600 may convert the stored electrical energy into power and provide the converted power to at least one low power operation module in the standby mode in which power is cut off. The low power operation module may include a microcomputer and a wireless communication interface. The wireless communication interface may include, but is not limited to, at least one of a Wi-Fi module, a Bluetooth module, an IR module, a UWB module, and a Zigbee module.

The electronic device according to various embodiments disclosed herein may be one of various types of electronic devices. The electronic devices may include, for example, a display device, a portable communication device (e.g., a smartphone), a computer device, a portable multimedia device, a portable medical device, a camera, a wearable device, a home appliance, or the like. The electronic devices according to an embodiment of the disclosure are not limited to those described above.

The various embodiments and terms used herein are not intended to limit the technical features described herein to specific embodiments and should be understood to include various modifications, equivalents, or substitutes of the embodiment. For example, an element expressed in a singular should be understood as a concept including a plurality of elements unless the context clearly refers only the singular. It should be understood that the term ‘and/or’ as used herein is intended to encompass any and all possible combinations of one or more of the enumerated items. As used in the disclosure, the terms such as ‘comprise(s)’, ‘include(s)’ ‘have/has’, ‘configured of’, etc. are only intended to designate that the features, components, parts, or combinations thereof described in the disclosure exist, and the use of these terms is not intended to exclude the possibility of the presence or addition of one or more other features, components, parts, or combinations thereof. In this disclosure, each of the phrases such as “A or B”, “at least one of A and B”, “at least one of A or B”, “A, B or C”, “at least one of A, B and C”, and “at least one of A, B, or C” may include any one of the items enumerated together in a corresponding one of the phrases, or all possible combinations thereof. Terms such as “the first”, “the second”, or “first”, or “second” may be used simply to distinguish a corresponding component from another corresponding component, and do not limit the corresponding components in view of other aspect (e.g., importance or order).

The term “module” or “unit” used in various embodiments of the disclosure may include a unit implemented in hardware, software, or firmware, or any combination thereof, and be used interchangeably with terms such as e.g., logic, logic block, part, component, or circuitry, for example. The module or unit may be a minimum unit or a part of the integrally configured component or the component that performs one or more functions. For example, according to an embodiment, the module or unit may be implemented in the form of an application-specific integrated circuit (ASIC).

The term “in case ˜” used in various embodiments of the disclosure, may be construed to refer, for example, to “when ˜” or “when ˜”, or “in response to determining ˜” or “in response to detecting ˜”, depending on the context. Similarly, the term “when it is determined that ˜” or “when it is detected that ˜” may be interpreted to refer, for example, to “upon determining ˜” or “in response to determining ˜”, or “upon detecting ˜” or “in response to detecting ˜”, depending on the context.

The program executed by the electronic device 600 described herein may be implemented as a hardware component, a software component, and/or a combination of the hardware component and the software component. The program may be executed by any system capable of executing computer readable instructions.

Software may include a computer program, codes, instructions, or a combination of one or more of these, and may configure a processing unit to perform operations as desired or command the processing unit independently or in combination (collectively). The software may be implemented as a computer program including instructions stored in a computer-readable storage medium. The computer-readable storage medium may include, for example, a magnetic storage medium (e.g., read-only memory (ROM), random-access memory (RAM), floppy disk, hard disk, and so on), an optically readable medium (e.g., CD-ROM, digital versatile disc (DVD), or the like) and so on. The computer-readable storage medium may be distributed among network-connected computer systems, so that the computer-readable code may be stored and executed in a distributed manner. The computer program may be distributed (e.g., downloaded or uploaded) by online, either via an application store (e.g. Play Store™) or directly between two user devices (e.g., smartphones). In the case of online distribution, at least a part of the computer program product may be temporarily stored or temporarily generated in a machine-readable storage medium such as a memory of a server of a manufacturer, a server of an application store, or a relay server.

According to various embodiments, each component (e.g., module or program) of the above-described components may include a singular or a plurality of entities, and some of the plurality of entities may be separated and placed into other components. According to various embodiments, one or more components or operations among the above-described corresponding components may be omitted, or one or more other components or operations may be added thereto. Alternatively or additionally, a plurality of components (e.g., a module or a program) may be integrated into one component. In this case, the integrated component may perform one or more functions of each component of the plurality of components identically or similarly to those performed by the corresponding component among the plurality of components prior to the integration. According to various embodiments, operations performed by a module, program, or other component may be executed sequentially, in parallel, repeatedly or heuristically, or one or more of the operations may be executed in a different order or omitted, or one or more other operations may be added thereto.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. An electronic device, comprising:
at least one power management integrated circuit (PMIC) configured to convert energy generated by at least one component of the electronic device into electrical energy;
a memory storing at least one instruction; and
at least one processor electrically connected to the memory and configured to execute the at least one instruction, wherein the at least one processor is configured to:
determine an operation state of the at least one component;
determine whether to drive at least one corresponding PMIC, based on the operation state; and
drive the at least one corresponding PMIC based on the determination of whether to drive the at least one PMIC.

2. The electronic device of claim 1, wherein the at least one PMIC comprises at least one of a photoelectric element PMIC, a radio frequency (RF) PMIC, a thermoelectric PMIC, and a piezoelectric PMIC.

3. The electronic device of claim 1, wherein the at least one component of the electronic device comprises at least one of a display panel, a speaker, a wireless communication interface, a direct current (DC) power supply, a dimming controller, the at least one processor, and a main board on which the at least one processor is mounted.

4. The electronic device of claim 3, wherein the operation state of the at least one component comprises at least one of a state in which a backlight of the display panel is in an on state, a state in which a volume of the speaker is equal to or larger than a predetermined volume, a state in which the wireless communication interface is operating, and a state in which a temperature of any of the DC power supply, the dimming controller, the at least one processor, and the main board is equal to or larger than a predetermined temperature.

5. The electronic device of claim 3, wherein the energy comprises at least one of light energy, vibration energy, RF energy, and thermal energy.

6. The electronic device of claim 5, wherein the light energy is generated while a backlight of the display panel is in an on state,
wherein the vibration energy is generated when a volume of the speaker is equal to or larger than a predetermined volume,
wherein the RF energy is generated while the wireless communication interface is operating, and
wherein the thermal energy is generated when a temperature of any of the DC power supply, the dimming controller, the at least one processor, and the main board is larger than or equal to a predetermined temperature.

7. The electronic device of claim 1, further comprising a charging supply configured to store electrical energy converted by the at least one PMIC.

8. The electronic device of claim 7, further comprising a standby mode power supply configured to convert the electrical energy stored in the charging supply into power and provide the converted power to at least one low power operation module in a standby mode in which power is cut off.

9. The electronic device of claim 8, wherein the low power operation module comprises a microcomputer, a Wi-Fi module, a Bluetooth module, and an infrared (IR) module.

10. A method for energy harvesting by an electronic device, the method comprising:
determining an operation state of at least one component of the electronic device;
determining whether to drive at least one corresponding PMIC, based on the operation state;
driving the at least one corresponding PMIC based on determining whether to drive the at least one PMIC; and
converting energy generated by the at least one component into electrical energy in response to driving the at least one corresponding PMIC.

11. The method of claim 10, wherein the at least one PMIC includes at least one of a photoelectric element PMIC, a radio frequency (RF) PMIC, a thermoelectric PMIC, and a piezoelectric PMIC.

12. The method of claim 10, wherein the at least one component of the electronic device includes at least one of a display panel, a speaker, a wireless communication interface, a direct current (DC) power supply, a dimming controller, at least one processor, and a main board on which the at least one processor is mounted.

13. The method of claim 12, wherein the operation state of the at least one component includes at least one of a state in which a backlight of the display panel is in an on state, a state in which a volume of the speaker is equal to or larger than a predetermined volume, a state in which the wireless communication interface is operating, and a state in which a temperature of any one of the DC power supply, the dimming controller, the at least one processor, and the main board is equal to or larger than a predetermined temperature.

14. The method of claim 12, wherein the energy includes at least one of light energy, vibration energy, RF energy, and thermal energy.

15. The method of claim 14, wherein the light energy is generated while a backlight of the display panel is in an on state,
wherein the vibration energy is generated when a volume of the speaker is equal to or larger than a predetermined volume,
wherein the RF energy is generated while the wireless communication interface is operating, and
wherein the thermal energy is generated when a temperature of any of the DC power supply, the dimming controller, the at least one processor, and the main board is larger than or equal to a predetermined temperature.

16. The method of claim 10, further comprising storing electrical energy converted by the driven at least one PMIC.

17. The method of claim 16, further comprising converting the stored electrical energy into power and providing the converted power to at least one low power operation module in a standby mode in which power is cut off.

18. The method of claim 17, wherein the low power operation module includes a microcomputer, a Wi-Fi module, a Bluetooth module, and an IR module.
